(19) United States
(12) Patent Application Publication
(10) Pub. No.: US 2006/0168498 A1
(43) Pub. Date: Jul. 27, 2006

(54) Test apparatus and program for testing a dut

(75) Inventor: Masaki Fujiwara, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/304,983

(22) Filed: Dec. 15, 2005

Related U.S. Application Data
(63) Continuation of application No. PCT/JP04/08139, filed on Jun. 10, 2004.

(30) Foreign Application Priority Data
Jun. 19, 2003 (JP) 2003-175437

(51) Int. Cl. H03M 13/00

(52) U.S. Cl. 714/762

(57) ABSTRACT

There is provided a test apparatus including a pattern generator that generates test patterns, a logic comparator that decides the good or bad of the electronic device, and a fail memory that stores decision results of the logic comparator every address of the electronic device, in which the pattern generator includes a burst length storing section that stores a test burst length, an address generator that sequentially generates addresses included in an address area determined by the first address and the test burst length to supply the generated addresses to the fail memory, and an instruction memory that stores a sequence of instructions to be sequentially executed to generate test patterns, includes an instruction by which the test burst length should be updated in the sequence, and updates the test burst length stored on the burst length storing section when the instruction by which the test burst length should be updated has been in the sequence.

### CROSS REFERENCE TO THE RELATED APPLICATION

This is a continuation application of PCT/JP2004/008139 filed on Jun. 10, 2004 which claims priority from a Japanese Patent Application No. JP 2003-175437 filed on Jun. 19, 2003, the contents of which are incorporated herein by reference.

### BACKGROUND OF THE INVENTION

1. Field of the Invention

The present invention relates to a test apparatus that tests an electronic device and a program that makes a test device function. More particularly, the present invention relates to a test apparatus that tests an electronic device having a burst function.

2. Description of Related Art

Generally, when an electronic device such as a memory is tested, test patterns such as data to be written in, addresses to be written in, and control signals are supplied to the electronic device, and a bad cell of the electronic device is detected by comparing output signals output from the electronic device with expected values. Moreover, comparison results between the output signals and the expected values are stored on a fail memory every address (cell) of the electronic device. At this time, a test apparatus supplies the same address as that supplied to the electronic device to the fail memory after delaying the address supplied to the electronic device for predetermined time.

Moreover, the electronic device to be test includes a memory having a burst function. The burst function means that data stored in an address area determined by a given first address and a preset burst length are sequentially output. When such an electronic device is tested, a first address of the data to be output by the burst length is supplied to the electronic device. On the contrary, it is necessary to supply an address corresponding to each data of output signals to the fail memory. For this reason, a conventional test apparatus generates burst addresses to be supplied to the fail memory.

Moreover, the electronic device has a plurality of lap types such as a sequential mode in which addresses corresponding to the data to be output are sequenced in an ascending order and an interleaved mode in which the corresponding addresses are sequenced in an order different from that of the sequential mode.

The test apparatus generates a burst length preset in the electronic device and burst addresses to be supplied to the fail memory according to a lap type. For example, the test apparatus has a means for storing the burst length preset in the electronic device and the lap type, and generates burst addresses based on the burst length the lap type stored on the storing means.

However, since the conventional test apparatus stores these burst length and lap type on a static storing means, it is not possible to change the burst length and the lap type during testing the electronic device. In other words, when testing the electronic device in a different operation mode, since these settings must be changed after stopping the test of the electronic device, it was difficult to efficiently test the electronic device.

### SUMMARY OF THE INVENTION

Therefore, it is an object of the present invention to provide a test apparatus and a program that can solve the foregoing problems. The above and other objects can be achieved by combinations described in the independent claims. The dependent claims define further advantageous and exemplary combinations of the present invention.

To solve this object, according to the first aspect of the present invention, there is provided a test apparatus that tests an electronic device having a burst output function continuously outputting data stored in an address area determined by a given first address by the number of data determined by a preset burst length setting value, in synchronization with given system clocks. The test apparatus includes: a pattern generator that generates test patterns to be input to the electronic device according to a test program for testing the electronic device; a logic comparator that decides the good or bad of the electronic device based on output signals output from the electronic device according to the test patterns; and a fail memory that stores decision results of the logic comparator every address of the electronic device, in which the pattern generator includes: a burst length storing section that stores a test burst length identical with the burst length setting value; an address generator that generates the first address to be supplied to the electronic device according to the test program and sequentially generates addresses included in an address area determined by the first address and the test burst length to supply the generated addresses to the fail memory; and an instruction memory that stores a sequence of instructions to be sequentially executed to generate test patterns to be input to the electronic device, includes an instruction by which the test burst length should be updated in the sequence, and updates the test burst length stored on the burst length storing section when the instruction by which the test burst length should be updated has been in the sequence.

The electronic device may include: a sequential mode sequentially outputting the data stored on the address area so that the corresponding addresses ascends or descends from the first address; and an interleaved mode sequentially outputting the data stored on the address area in an order different from the sequential mode, the electronic device may select which one of the sequential mode and the interleaved mode operates the device based on a preset lap type setting value, the address generator may generate sequential burst addresses in which each of the addresses included in the address area is sequenced in an ascending order or a descending order from the first address and interleaved burst addresses in which each of the addresses included in the address area is sequenced in an order different from the sequential burst addresses, the pattern generator may further include: a selector that selects which one of the sequential burst addresses and the interleaved burst addresses and supplies the selected addresses to the fail memory; and a lap type storing section that stores a test lap type showing which one of the sequential burst addresses and the interleaved burst addresses is selected and controls the selector based on the stored test lap type, and the instruction memory may include an instruction by which the test lap type should be updated in the sequence and update the test lap type stored on the lap type storing section when the instruction by which the test lap type should be updated has been in the sequence.

The instruction memory may hold a test burst length to be next stored on the burst length storing section and newly store the test burst length to be next stored on the burst length storing section when an instruction by which the test burst length should be updated has been in the sequence.

The instruction memory may further include an instruction for changing the burst length setting value set in the electronic device in the sequence and update the test burst length in the burst length storing section after changing the burst length setting value.

According to the second aspect of the present invention, there is provided a program that makes a test apparatus test an electronic device having a burst output function continuously outputting data stored in an address area determined by a given first address by the number of data determined by a preset burst length setting value, in synchronization with given system clocks. The program makes the test apparatus function as: a pattern generator that generates test patterns to be input to the electronic device according to a test program for testing the electronic device; a logic comparator that decides the good or bad of the electronic device based on output signals output from the electronic device according to the test patterns; and a fail memory that stores decision results of the logic comparator every address of the electronic device, and the program makes the pattern generator function as: a burst length storing section that stores a test burst length identical with the burst length setting value; an address generator that generates the first address to be supplied to the electronic device according to the test program and sequentially generates addresses included in an address area determined by the first address and the test burst length to supply the generated addresses to the fail memory; and an instruction memory that stores a sequence of instructions to be sequentially executed to generate test patterns to be input to the electronic device, includes an instruction by which the test burst length should be updated in the sequence, and updates the test burst length stored on the burst length storing section when the instruction by which the test burst length should be updated has been in the sequence.

The summary of the invention does not necessarily describe all necessary features of the present invention. The present invention may also be a sub-combination of the features described above.

According to the present invention, although an electronic device is under a test, it is possible to update a burst length and a lap type set in the electronic device and a test apparatus.

### BRIEF DESCRIPTION OF THE DRAWINGS

FIG. 1 is a view exemplary showing a configuration of a test apparatus according to an embodiment of the present invention.

FIG. 2 is a view exemplary showing a configuration of a pattern generator.

FIG. 3 is a view exemplary showing a configuration of an address generating section.

FIG. 4 is a view exemplary showing a test program stored on an instruction memory.

FIG. 5 is a view exemplary showing a configuration of a computer that controls a test apparatus.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

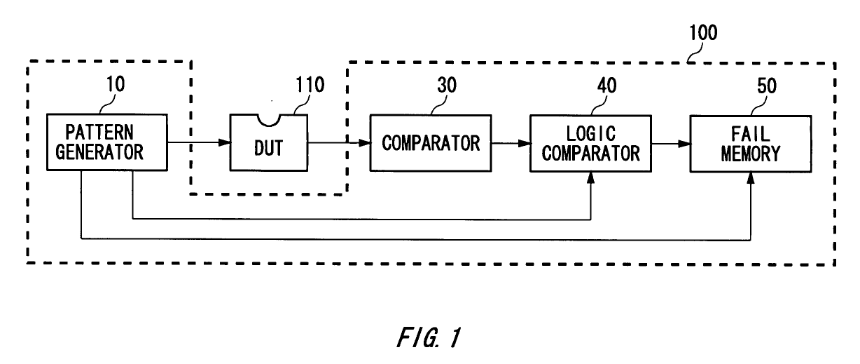

FIG. 1 is a view exemplary showing a configuration of a test apparatus 100 according to an embodiment of the present invention. The test apparatus 100 tests an electronic device 110. In this example, the electronic device 110 is a memory such as SDRAM having a burst function. Here, the burst function means an operation sequentially outputting data stored in a contiguous address space from a given first address. Moreover, the test apparatus 100 includes a pattern generator 10, a comparator 30, a logic comparator 40, and a fail memory 50.

The pattern generator 10 generates test patterns to be supplied to the electronic device 110 in order to perform a test for the electronic device 110. Moreover, the pattern generator 10 supplies a signal selecting one of a mode to write electronic data into the electronic device 110 and a mode to read electron data stored on the electronic device 110. When the electronic data is written into the electronic device 110, the pattern generator 10 generates a signal addressing the electronic device 110 and data to be written into the designated address and supplies the generated signal and data to the electronic device 110. Moreover, the pattern generator 10 supplies a signal addressing the electronic device 110 to the electronic device 110 when the electronic data is read from the electronic device 110.

The comparator 30 receives the data read from the electronic device 110 as an output signal, and converts the output signal into a digital signal indicative of H logic or L logic based on whether a level of each data of the output signal is larger than a predetermined level.

The logic comparator 40 compares the output signal with an expectation pattern generated from the pattern generator 10, and decides the good or bad of the electronic device 110. For example, the pattern generator 10 generates an expectation pattern having a pattern identical with the test pattern supplied to the electronic device 110.

The fail memory 50 stores comparison results between the output signal and the expectation pattern every address of the electronic device 110. It is possible to decide which of addresses of the electronic device 110 has a failure by analyzing the comparison results stored on the fail memory 50.

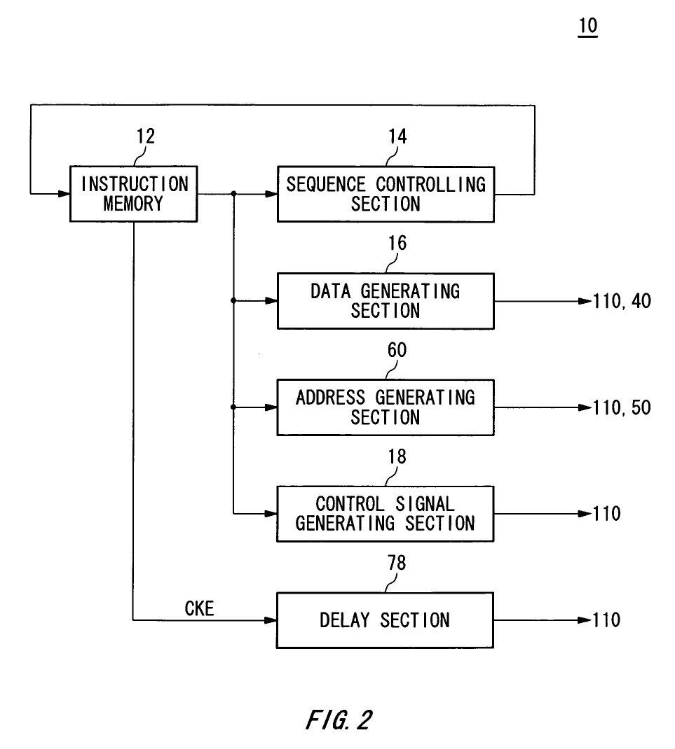

FIG. 2 is a view exemplary showing a configuration of the pattern generator 10. The pattern generator 10 has an instruction memory 12, a sequence controlling section 14, a data generating section 16, an address generating section 60, and a control signal generating section 18.

The instruction memory 12 stores an instruction controlling a sequence to generate a test pattern, data and an operation instruction of the data to generate a test pattern to be supplied to the electronic device 110, address data by which data should be written into the electronic device 110, a control signal to control a mode of the electronic device 110, and so on.

The sequence controlling section 14 selects whether the test pattern is generated by means of either of the data, the operation instruction, the address data, or the control signal that is stored on the instruction memory 12, based on an instruction group stored on the instruction memory 12. The data and operation instruction, the address data, and the control signal that are selected by the sequence controlling section 14 are respectively sent to the data generating section 16, the address generating section 60, and the control signal generating section 18.

The data generating section 16 generates the test data to be supplied to the electronic device 110 based on the data and the operation instruction received from the instruction memory 12. Moreover, the data generating section 16 supplies the test data to the logic comparator 40 as an expected value data.

The address generating section 60 generates address data showing at which address of the electronic device 110 should be stored the test data generated from the data generating section 16. Moreover, the address generating section 60 generates an address corresponding to the decision result by the logic comparator 40 and supplies the generated address to the fail memory 50.

The control signal generating section 18 controls the electronic device 110 based on a control signal received from the instruction memory 12. For example, the control signal generating section 18 controls an operation mode showing whether the data is written into or not is read from the electronic device 110.

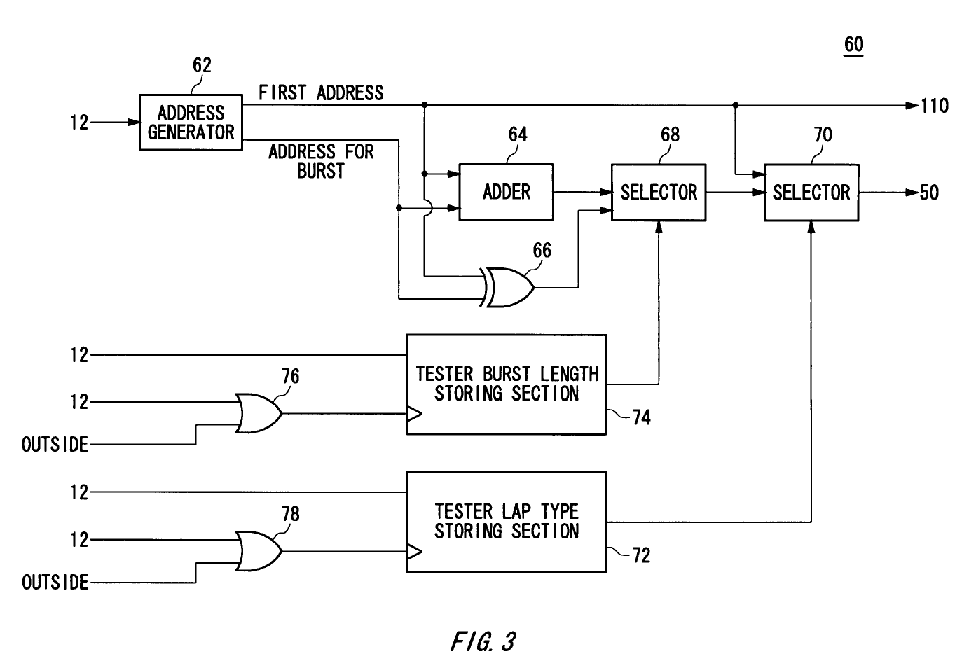

FIG. 3 is a view exemplary showing a configuration of the address generating section 60. The address generating section 60 has an address generator 62, an adder 64, an exclusive OR circuit 66, a selector 68, a selector 70, a burst length storing section 74, a lap type storing section 72, an OR circuit 76, and an OR circuit 78.

The electronic device 110 in this example includes a sequential mode sequentially outputting data stored in an address area determined by a given first address and a burst length setting value previously set in the electronic device 110 so that corresponding addresses ascend or descend from the first address and an interleaved mode sequentially outputting the data stored in the address area in an order different from the sequential mode. Moreover, the electronic device 110 selects whether it operates in the sequential mode or not in the interleaved mode based on the preset lap type setting value. These burst length setting values and lap type setting value are set by, e.g., a mode register or a set command.

The address generator 62 generates a first address in an address area in which the data output from the electronic device 110 in a burst mode are stored according to an address data given from the instruction memory 12. The address generator 62 supplies the generated first address to the electronic device 110, the adder 64, and the exclusive OR circuit 66. Moreover, the address generator 62 generates an address for burst to generate a burst address from the first address. In this example, the address generator 62 generates a first address of which address is shown by a binary number and an address for burst in which a counter value increasing by one from zero is shown by a binary number.

The adder 64 generates a sequential burst address made by sequentially adding the address for burst to the first address. Moreover, the exclusive OR circuit 66 generates an interleaved burst address made by sequentially computing an exclusive OR between each bit of the first address and each bit of the address for burst, for each address for burst.

The selector 68 selects either of the sequential burst address generated from the adder 64 and the interleaved burst address generated from the exclusive OR circuit 66, and outputs the selected address.

The lap type storing section 72 stores a test lap type showing whether the selector 68 should select the sequential burst address or not the interleaved burst address, and controls the selector 68 based on the stored test lap type. In this example, the lap type storing section 72 stores a test lap type identical with a lap type setting value preset in the electronic device 110.

Moreover, the burst length storing section 74 stores a test burst length identical with a burst length setting value set in the electronic device 110. Then, the selector 70 receives the first address generated from the address generator 62 and either of the burst addresses selected by the selector 68. Then, when the electronic device 110 performs the output in a burst mode, the selector 70 fits the burst address received from the selector 68 in the first address received from the address generator 62, and supplies the result to the fail memory 50. In this case, the length of the burst address that the selector 70 supplies to the fail memory 50 is controlled by the test burst length stored on the burst length storing section 74. For example, the selector 70 supplies burst addresses corresponding to four cycles to the fail memory 50 when the burst length storing section 74 stores four as the test burst length. Moreover, when the electronic device 110 does not perform the output in a burst mode, the selector 70 supplies the first address generated from the address generator 62 to the fail memory 50.

In other words, the address generating section 60 generates a first address to be supplied to the electronic device 110 according to a test program, and sequentially generates addresses in an address area determined by the first address and the test burst length, in order to supply the addresses to the fail memory 50. Moreover, the address generating section 60 can generate sequential burst addresses in which each of the addresses included in an address area by determined by the first address and the test burst length is sequenced in an ascending order or a descending order from the first address and interleaved burst addresses in which each of the addresses included in the address area is sequenced in an order different from the sequential burst addresses. By such a control, it is possible to supply a burst address according to an operation mode of the electronic device 11 to the fail memory 50.

Moreover, the test lap type and the test burst length stored on the lap type storing section 72 and the burst length storing section 74 are updated by the instruction memory 12. The instruction memory 12 stores a sequence of instructions to be sequentially executed in order to generate the test pattern to be input into the electronic device 110, includes an instruction by which the test burst length should be updated in the sequence, and updates the test burst length stored on the burst length storing section 74 and the test lap type stored on the lap type storing section 72 when the instruction by which the test burst length should be updated has been in the sequence.

The OR circuit 76 and the OR circuit 78 control timing at which values stored on the lap type storing section 72 and the burst length storing section 74 are updated. For example, the OR circuit 76 is supplied with a control signal showing H logic from the instruction memory 12 or the outside at the timing at which the test lap type stored on the lap type storing section 72 should be updated, and controls the lap type storing section 72 to be able to be updated when the control signal shows H logic. At this time, the lap type storing section 72 is supplied with the test lap type to be updated from the instruction memory 12, and the test lap type is updated.

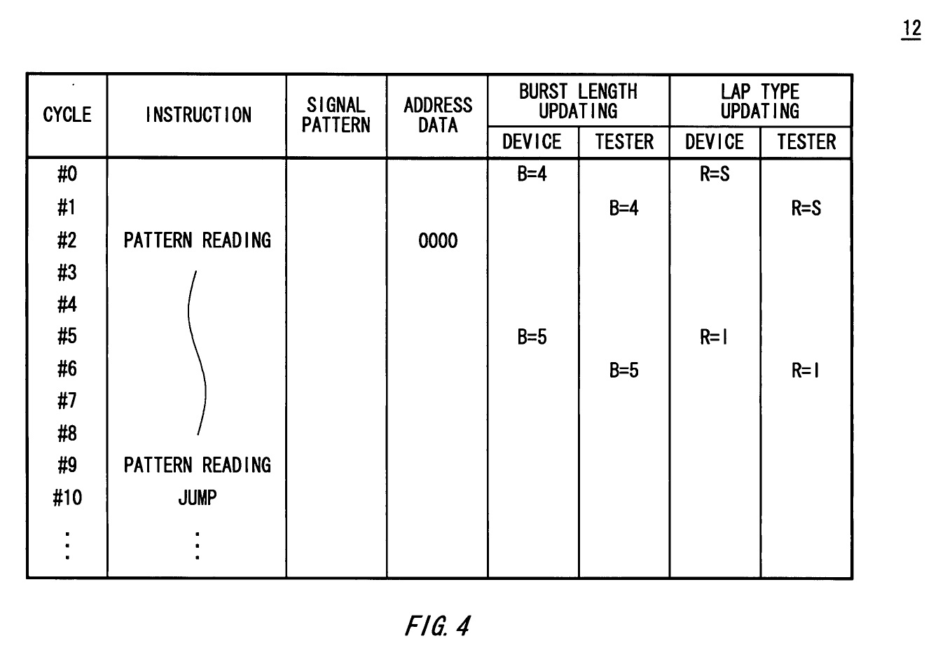

FIG. 4 is a view exemplary showing a test program stored on the instruction memory 12. The instruction memory 12 includes an instruction, by which the test lap type, the lap type setting value, the test burst length, and the burst length setting value should be updated, in the stored sequence. When the instruction by which the test lap type or the like should be updated has been in the sequence, the instruction memory 12 updates the corresponding burst length or lap type.

In this example, the instruction memory 12 stores an instruction group operating the sequence controlling section 14, an instruction updating a signal pattern, an address data, a test burst length, and a burst length setting value, and an instruction updating a test lap type and a lap type setting value. The sequence controlling section 14 controls whether generating a test pattern using any signal pattern or address data stored on the instruction memory 12 according to the instruction group stored on the instruction memory 12. The instruction group is an instruction group including so-called LOOP, JUMP, NOP, or the like.

Moreover, the signal pattern includes data to generate the test data, a data operation instruction, or the like. Moreover, the address data shows an address of the electronic device 110 that should store the corresponding signal pattern. Moreover, when reading data stored on the electronic device 110, the address data shows an address at which the data is stored. For example, when the electronic device 110 performs the output in a burst mode, the address data may be data indicative of a first address of the burst output.

The instruction to update a test burst length and a burst length setting value is an instruction indicative of a new burst length that should be updated next in the cycle in which each burst length should be updated. Moreover, the instruction to update a test burst length and a burst length setting value may be stored in association with an instruction to operate the sequence controlling section 14. Moreover, an instruction to update a test lap type and a lap type setting value is similar to the above.

Moreover, it is preferable that the instruction memory 12 changes a burst length or a lap type set in the electronic device 110 and then changes a burst length or a lap type set in the test apparatus 100 when updating each burst length or lap type. Such a control can easily be realized according to a position at which an instruction to update a burst length or a lap type is arranged in a sequence.

According to the instruction memory 12 in this example, since an instruction to update a burst length or a lap type is included in a sequence to generate a test pattern, the burst length and the lap type set in the electronic device 110 and the test apparatus 100 can be updated even if the electronic device 110 is under a test.

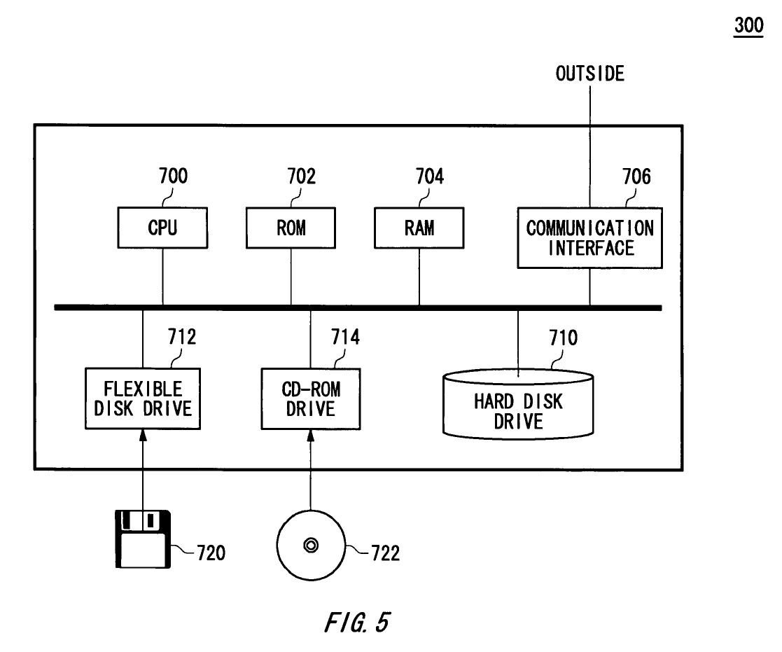

FIG. 5 is a view exemplary showing a configuration of a computer 300 for controlling the test apparatus 100. In this example, the computer 300 stores a program making the test apparatus 100 function as the test apparatus 100 described in FIGS. 1 to 4. Moreover, the computer 300 may function as the test apparatus 100.

The computer 300 includes a CPU 700, a ROM 702, a RAM 704, a communication interface 706, a hard disk drive 710, a flexible disk drive 712, and a CD-ROM drive 714. The CPU 700 operates based on a program stored on the ROM 702, the RAM 704, the hard disk drive 710, the flexible disk 720, and the CD-ROM 722.

For example, the program making the test apparatus 100 function makes the test apparatus 100 function as the pattern generator 10, the comparator 30, the logic comparator 40, and the fail memory 50 described in reference to FIG. 1. Moreover, the program causes the pattern generator 10 to function as the instruction memory 12, the sequence controlling section 14, the data generating section 16, the address generating section 60, and the control signal generating section 18 described in reference to FIG. 2. Moreover, the program makes the address generating section 60 function as the address generator 62, the adder 64, the exclusive OR circuit 66, the selector 68, the selector 70, the lap type storing section 72, the burst length storing section 74, the OR circuit 76, and the OR circuit 78 described in reference to FIG. 3.

The communication interface 706 communicates with each component of the test apparatus 100, and receives information related to a state of each component and sends a control signal for control each component.

The hard disk drive 710, the ROM 702 or the RAM 704 that is an example of a storage device stores configuration information and a program to make the CPU 700 operate. Moreover, the program may be stored on a recording medium such as the flexible disk 720 and the CD-ROM 722.

When the flexible disk 720 stores a program, the flexible disk drive 712 reads the program from the flexible disk 720 and provides it to the CPU 700. When the CD-ROM 722 stores a program, the CD-ROM drive 714 reads the program from the CD-ROM 722 and provides it to the CPU 700.

Moreover, a program may directly be read from a recording medium to the RAM to be executed, or may be read to the RAM 704 to be executed after being once installed in the hard disk drive 710. Furthermore, the program may be stored on a single recording medium or a plurality of recording media. Moreover, a program stored on a recording medium may provide each function jointly with an operating system. For example, the program may entrust the operating system with a part or all of functions, and provide the functions based on an answer from the operating system.

A recording medium for storing a program may include an optical recording medium such as DVD and PD, a magneto-optical recording medium such as MD, a tape medium, a magnetic recording medium, a semiconductor memory such as an IC card and a miniature card, in addition to the flexible disk and the CD-ROM. Moreover, a recording medium may include a storage device such as a hard disk and a RAM that is provided in a server system connected to a private telecommunication network and Internet.

Although the present invention has been described by way of an exemplary embodiment, it should be understood that those skilled in the art might make many changes and substitutions without departing from the spirit and the scope of the present invention. It is obvious from the definition of the appended claims that embodiments with such modifications also belong to the scope of the present invention.

As apparent from the above descriptions, according to the present invention, it is possible to update a burst length and a lap type set in an electronic device and a test apparatus even though the electronic device is under a test.

What is claimed is:

1. A test apparatus that tests an electronic device having a burst output function continuously outputting data stored in an address area determined by a given first address by the number of data determined by a preset burst length setting value, in synchronization with given system clocks, comprising:
a pattern generator that generates test patterns to be input to the electronic device according to a test program for testing the electronic device;
a logic comparator that decides the good or bad of the electronic device based on output signals output from the electronic device according to the test patterns; and
a fail memory that stores decision results of the logic comparator every address of the electronic device, and said pattern generator comprising:
a burst length storing section that stores a test burst length identical with the burst length setting value;
an address generator that generates the first address to be supplied to the electronic device according to the test program and sequentially generates addresses included in an address area determined by the first address and the test burst length to supply the generated addresses to the fail memory; and
an instruction memory that stores a sequence of instructions to be sequentially executed to generate test patterns to be input to the electronic device, includes an instruction by which the test burst length should be updated in the sequence, and updates the test burst length stored on said burst length storing section when the instruction by which the test burst length should be updated has been in the sequence.

2. The test apparatus as claimed in claim 1, wherein
the electronic device comprises:
a sequential mode sequentially outputting the data stored on the address area so that the corresponding addresses ascends or descends from the first address; and
an interleaved mode sequentially outputting the data stored on the address area in an order different from the sequential mode,
the electronic device selects which one of the sequential mode and the interleaved mode operates the device based on a preset lap type setting value,
the address generator generates sequential burst addresses in which each of the addresses included in the address area is sequenced in an ascending order or a descending order from the first address and interleaved burst addresses in which each of the addresses included in the address area is sequenced in an order different from the sequential burst addresses,
said pattern generator further comprises:
a selector that selects which one of the sequential burst addresses and the interleaved burst addresses and supplies the selected addresses to said fail memory; and
a lap type storing section that stores a test lap type showing which one of the sequential burst addresses and the interleaved burst addresses is selected and controls the selector based on the stored test lap type, and
the instruction memory includes an instruction by which the test lap type should be updated in the sequence and updates the test lap type stored on the lap type storing section when the instruction by which the test lap type should be updated has been in the sequence.

3. The test apparatus as claimed in claim 1, wherein the instruction memory holds a test burst length to be next stored on the burst length storing section and newly stores the test burst length to be next stored on the burst length storing section when an instruction by which the test burst length should be updated has been in the sequence.

4. The test apparatus as claimed in claim 1, wherein the instruction memory further comprises an instruction for changing the burst length setting value set in the electronic device in the sequence and updates the test burst length in the burst length storing section after changing the burst length setting value.

5. A program that makes a test apparatus test an electronic device having a burst output function continuously outputting data stored in an address area determined by a given first address by the number of data determined by a preset burst length setting value, in synchronization with given system clocks, the program making the test apparatus function as:
a pattern generator that generates test patterns to be input to the electronic device according to a test program for testing the electronic device;
a logic comparator that decides the good or bad of the electronic device based on output signals output from the electronic device according to the test patterns; and
a fail memory that stores decision results of the logic comparator every address of the electronic device, and
the program making said pattern generator function as:
a burst length storing section that stores a test burst length identical with the burst length setting value;
an address generator that generates the first address to be supplied to the electronic device according to the test program and sequentially generates addresses included in an address area determined by the first address and the test burst length to supply the generated addresses to the fail memory; and
an instruction memory that stores a sequence of instructions to be sequentially executed to generate test patterns to be input to the electronic device, includes an instruction by which the test burst length should be updated in the sequence, and updates the test burst length stored on said burst length storing section when the instruction by which the test burst length should be updated has been in the sequence.
